(19) United States
(12) Patent Application Publication
(10) Pub. No.: US 2016/0218183 A1
(43) Pub. Date: Jul. 28, 2016

(54) DIAMOND MULTILAYER STRUCTURE

(71) Applicant: Panasonic Intellectual Property Management Co., Ltd., Osaka (JP)

(72) Inventors: SONGBAEK CHOE, Osaka (JP); ASAMIRA SUZUKI, Osaka (JP)

(21) Appl. No.: 14/975,659

(22) Filed: Dec. 18, 2015

(30) Foreign Application Priority Data
Jan. 28, 2015 (JP) 2015-014349

(51) Int. Cl. H01L 29/16; H01L 29/04; H01L 29/20

(52) U.S. Cl. CPC H01L 29/1602; H01L 29/2003; H01L 29/045

(57) ABSTRACT

A diamond multilayer structure comprises: a nitride semiconductor layer that have a first main surface and a second main surface and comprises a nitride semiconductor having a wurtzite structure and containing B; and a diamond layer located on the first main surface of the nitride semiconductor layer.

### BACKGROUND

1. Technical Field

The present disclosure relates to a diamond multilayer structure, a substrate for forming diamond semiconductor, and a diamond semiconductor device.

2. Description of the Related Art

Diamond is one of wide bandgap semiconductors each called the “ultimate semiconductor” and is expected to be applied, for example, to power devices thanks to its physical characteristics, such as a high breakdown electric field strength and a high thermal conductivity. In addition, although diamond is an indirect transition type semiconductor, light emission in a deep ultraviolet region having a wavelength of 235 nm can be obtained, and furthermore, diamond has a significantly higher exciton binding energy (80 meV) than room-temperature thermal energy (26 meV). Hence, diamond has also attracted attention as a novel deep ultraviolet device.

Unlike the other wide bandgap semiconductors, one of specific features of diamond is the conduction control. For example, AlN having bandgap energy approximately equivalent to that of diamond can hardly perform the conduction control and is almost an insulating material. However, in the case of diamond, when the surface thereof is terminated with hydrogen, holes are induced to the surface, and hence the surface conduction can be realized. In addition, when B or P is used as a dopant, and excessive doping at a level of 10²⁰ cm⁻³ is performed, conduction control at a relatively low resistance can be performed by hopping conduction. By the use of those conduction control techniques, a diamond field effect transistor which can be operated at a large current and a high frequency has been realized in recent years, and a diamond PIN light emission diode using an excessively doped n-type diamond layer has also been realized.

In addition, in recent years, since the NV center formed of nitrogen placed at a carbon site in a diamond lattice by substitution and a vacancy (hole) adjacent thereto can be used for single photon-spin control, the NV center has attracted attention. Hence, future development of quantum cryptography communication based on diamond has also been expected.

However, in order to enable the diamond devices as described above to be practically used in wide industrial fields, there are many problems to be overcome. Among those problems, a growth substrate essential for forming a diamond device structure is the most serious problem.

In order to grow a diamond device structure, a method of using a diamond substrate which is the same material as that for a diamond device structure, that is, a so-called homo-epitaxial growth method, is believed most desirable. However, the size of a high quality diamond substrate which is currently commercially available is small, such as approximately 1 cm square. Furthermore, the plane direction of this size diamond substrate is limited to the (100) plane. A (111) plane diamond substrate is realized only to have a size of several millimeters square. In consideration that a commercially available semiconductor device substrate formed of another material, such as Si, SiC, or sapphire, has a size of 2 to 8 inches, a large area substrate for diamond devices has been expected to be realized.

In order to solve the problem as described above, there has been reported an attempt in which a diamond film is formed on a different type substrate, the diameter of which can be easily increased. For example, Japanese Patent No. 5066651 has reported that a single crystal Ir layer, which is a metal film, is formed on a MgO substrate, and growth nuclei of diamond are formed at a high density by applying a bias to a growing Ir layer, so that diamond hetero growth is realized. However, by the method described above, a large diameter MgO substrate is necessarily used to form a single crystal Ir layer, and hence, there have been problems from technique and cost points of view. In the case described above, the large diameter indicates a large area, and the shape of the substrate is not limited to a circular shape.

In addition, a diamond hetero-epitaxial growth using a nitride semiconductor as an underlayer instead of a metal film has also been reported. For example, S. Koizumi, T. Murakami, K. Suzuki, and T. Inuzuka have reported in Applied Physics Letters, vol. 57, no. 6, pp. 563 to 565 that a diamond layer is hetero-epitaxially grown using cubic crystal BN (boron nitride) as an underlying substrate. The lattice constant of cubic crystal BN is close to that of diamond, and the difference therebetween is 1.3%. Accordingly, the cubic crystal BN is an ideal material as an underlayer for diamond hetero-epitaxial growth. According to the above document, a (111) plane diamond hetero-epitaxial film can be formed on the (111) plane of the cubic crystal BN.

### SUMMARY

One non-limiting and exemplary embodiment provides a diamond multilayer structure which can realize an increase in area thereof.

In one general aspect, the techniques disclosed here feature a diamond multilayer structure comprising: a nitride semiconductor layer that have a first main surface and a second main surface and comprises a nitride semiconductor having a wurtzite structure and containing B; and a diamond layer located on the first main surface of the nitride semiconductor layer. It should be noted that general or specific embodiments may be implemented as a structure, a substrate, a device, a method or any selective combination thereof.

According to the diamond multilayer structure of the present disclosure, the increase in area thereof can be realized.

Additional benefits and advantages of the disclosed embodiments will become apparent from the specification and drawings. The benefits and/or advantages may be individually obtained by the various embodiments and features of the specification and drawings, which need not all be provided in order to obtain one or more of such benefits and/or advantages.

### BRIEF DESCRIPTION OF THE DRAWINGS

FIG. 1A is a schematic view showing the crystal structure of cubic crystal BN;

FIG. 1B is a schematic view showing the crystal structure of hexagonal BN;

FIG. 1C is a schematic view showing the crystal structure of wurtzite BN;

FIG. 2A is a schematic view showing the atomic arrangement of a diamond crystal structure using the (111) plane as a main surface;

FIG. 2B is a schematic view showing the atomic arrangement of a wurtzite crystal structure using the (0001) plane as a main surface;

FIG. 3 is a graph showing B composition ratio dependence of the a-axis lattice constant of a BAlN mixed crystal and B composition ratio dependence of the degree of lattice mismatch of BAlN mixed crystal with diamond;

FIG. 4 is a graph showing the B composition ratio dependence of the degree of lattice mismatch between diamond and each of a BInN, a BGaN, and a BAlN mixed crystal;

FIG. 5 is a schematic cross-sectional view of a diamond multilayer structure of an embodiment;

FIG. 6 is a schematic cross-sectional view showing an embodiment of a diamond semiconductor device;

FIG. 7 is a schematic cross-sectional view showing another example of the embodiment of the diamond semiconductor device;

FIG. 8 is a view illustrating an alternate supply growth method of a nitride semiconductor layer in each of Examples 1 and 3;

FIG. 9 is a schematic cross-sectional view showing a diamond multilayer structure of Comparative Example 2;

FIG. 10A is a schematic view showing the structure of a diamond multilayer structure of Example 1 before a diamond layer is formed;

FIG. 10B shows diffraction peaks in a range of 25° to 43° which are the result obtained by x-ray diffraction measurement of a nitride semiconductor layer in Example 1;

FIG. 10C shows diffraction peaks in a range of 37° to 41° which are the result obtained by x-ray diffraction measurement of the nitride semiconductor layer in Example 1;

FIG. 11A shows the result of x-ray diffraction measurement of an m plane AlN layer;

FIG. 11B shows the result of x-ray diffraction measurement of a nitride semiconductor layer of Example 2;

FIG. 12A shows the result of x-ray diffraction measurement of an m plane GaN layer;

FIG. 12B shows the result of x-ray diffraction measurement of a nitride semiconductor layer of Example 3;

FIG. 13A is a surface optical microscope photo of a diamond layer of Comparative Example 1;

FIG. 13B is a surface optical microscope photo of a diamond layer of Example 1;

FIG. 14A is a surface optical microscope photo of a diamond layer of Comparative Example 2;

FIG. 14B is a surface optical microscope photo of a diamond layer of Example 3;

FIG. 15A shows the result of x-ray diffraction measurement of the diamond layer of Example 1;

FIG. 15B shows the result of x-ray diffraction measurement of a diamond layer of Example 2;

FIG. 16 is a cross-sectional transmission electron microscope photo of a diamond multilayer structure of Example 2; and

FIG. 17 is an enlarged photo of the interface between the diamond layer and the nitride semiconductor in the cross-sectional transmission electron microscope image of the diamond multilayer structure of Example 2.

### DETAILED DESCRIPTION

Hereinafter, embodiments of a diamond multilayer structure, a substrate for forming diamond semiconductor, a diamond semiconductor device, and a method for manufacturing a diamond multilayer structure of the present disclosure will be described. The diamond multilayer structure of the present disclosure comprises a nitride semiconductor layer having a wurtzite structure and containing B and a diamond layer formed thereon. First, the crystal structure of a nitride semiconductor layer on which a diamond layer is to be hetero-epitaxially grown and the crystal structure of a diamond layer will be described.

(Findings Conceiving Diamond Multilayer Structure of Present Disclosure)

Diamond has a cubic structure which is called a “diamond structure”. The lattice constant of the cubic crystal is 3.56 Å. On the other hand, when BN has a cubic structure, the lattice constant thereof is 3.61 Å. As described above, since the difference in lattice constant therebetween is very small, such as 1.3%, and the crystal structure is the same cubic structure, it is believed that cubic BN is useful as a substrate for hetero-epitaxially grown diamond.

Besides the cubic structure, BN may also have a stable hexagonal structure. Furthermore, as a metastable structure, BN may also have a wurtzite structure.

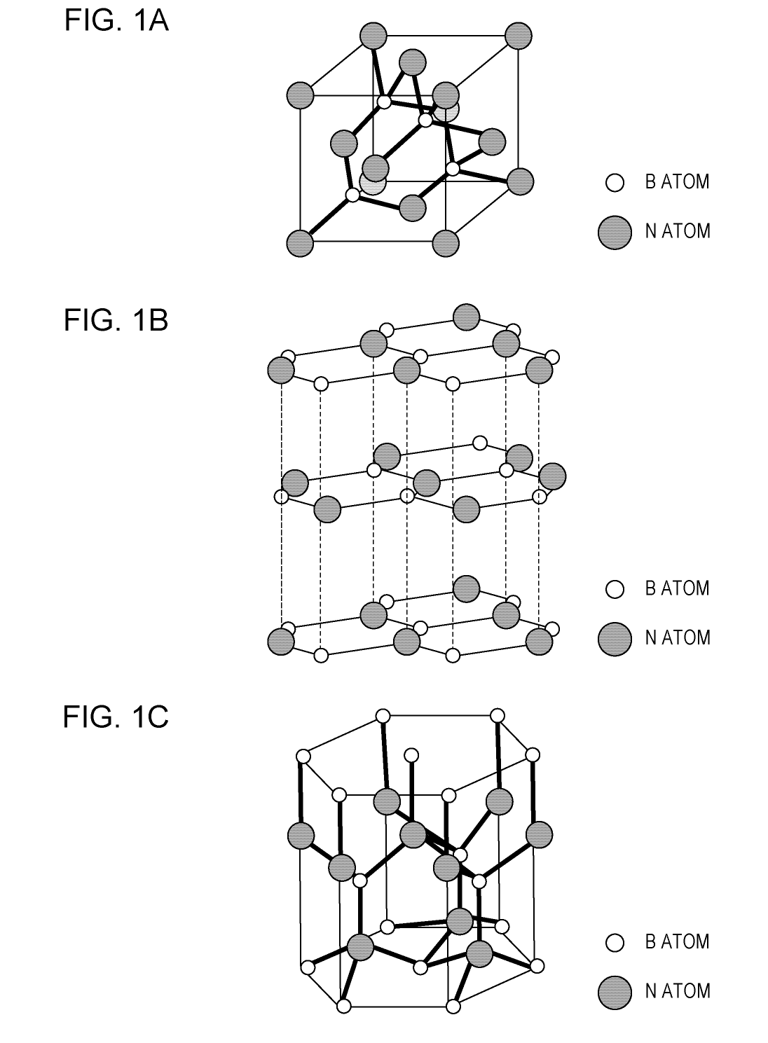

FIGS. 1A, 1B, and 1C schematically show a cubic structure, a hexagonal structure, and a wurtzite structure, respectively. In those drawings, a small while circle and a black circle represent a B atom and a N atom, respectively. The hetero-epitaxial growth of the diamond layer described in the above document written by S. Koizumi et al. is realized on the cubic structure shown in FIG. 1A.

As described above, in order to hetero-epitaxially grow a large diameter diamond layer, a large diameter substrate is required. However, it is not easy to realize a large diameter cubic BN substrate. Through intensive research to epitaxially grow a diamond layer using BN having a crystal structure other than the cubic structure, the inventors of the present disclosure have conceived to use a nitride semiconductor layer having a wurtzite structure.

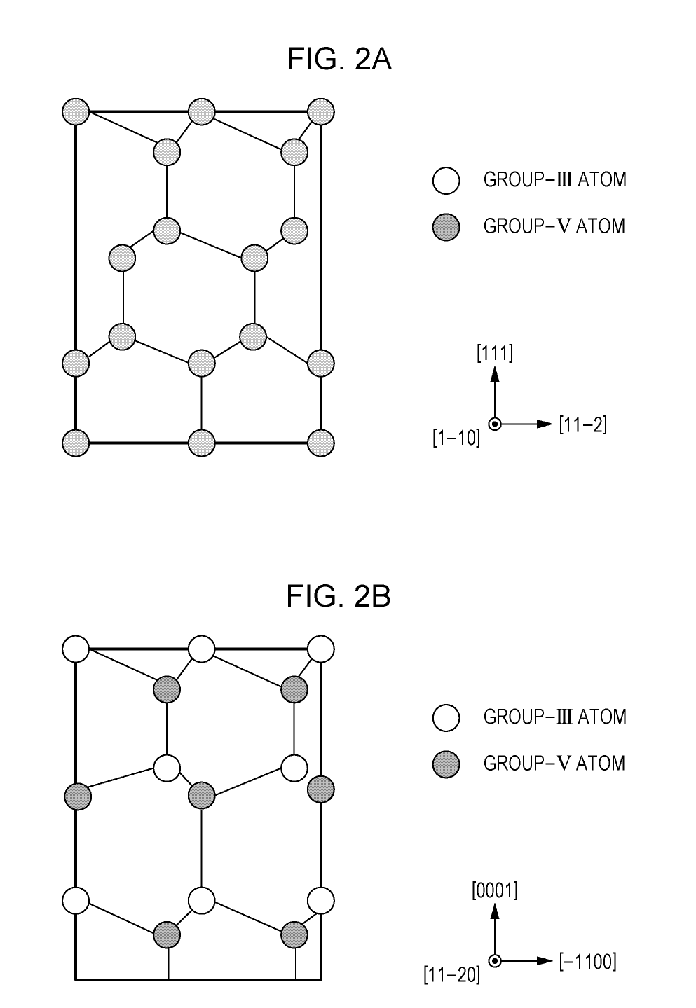

FIGS. 2A and 2B shows the atomic arrangement of the (111) plane of a cubic structure and that of the (0001) plane of a III-V compound having a wurtzite structure, respectively. As shown in FIG. 2A, the atom of the cubic structure has four coordinations by sp3 hybrid orbitals. In addition, a group-III atom and a group-V atom of the III-V compound each also have four coordination bonds, and hence, those two atomic arrangements described above are similar to each other. For example, it has been known that on the (111) plane of cubic Si which has a diamond structure, a (0001) plane GaN having a wurtzite structure can be grown. Hence, the cubic (111) plane of the diamond structure has relatively good compatibility with the (0001) plane of the wurtzite structure, and those planes are expected to have a plane direction relationship capable of performing hetero-epitaxial growth.

However, as for the BN crystal, although a hexagonal structure and a cubic structure are stable, a wurtzite structure is a metastable structure. Hence, a single crystal substrate or layer of BN having a wurtzite structure cannot be easily formed. Furthermore, it is also supposed that a large diameter single crystal substrate or layer of BN having a wurtzite structure is not easily formed.

In order to realize a large diameter hetero-epitaxially grown diamond, the inventors of the present disclosure have conceived to stabilize a wurtzite structure by using a BN mixed crystal formed by addition of a nitride semiconductor, such as InN, GaN, or AlN, to BN. In the nitride semiconductor, such as InN, GaN, or AlN, a stable wurtzite structure is present. In addition, those nitride semiconductors can be hetero-epitaxially grown on a silicon substrate or a sapphire substrate, each of which is a large diameter and low cost substrate. Hence, by the use of a BN mixed crystal having the (0001) plane of a wurtzite structure equivalent to the (111) plane of cubic BN which has been actually used as described above, an underlayer for hetero-epitaxial growth of a diamond layer can be formed. Alternatively, a BN crystal thin film can be formed on a crystal of a nitride semiconductor, such as InN, GaN, or AlN, having a wurtzite structure. That is, when a BN crystal thin film is formed on a crystal of a nitride semiconductor, such as InN, GaN, or AlN, having a wurtzite structure, a large diameter BN crystal having a wurtzite structure can be obtained. This BN crystal thin film may be used as an underlayer for hetero-epitaxial growth of a diamond layer. Hence, the increase in diameter, which has been difficult to be realized by cubic BN, can be achieved.

Hereinafter, with primarily reference to BAlN having a wurtzite structure as an example, a BN mixed crystal used in the present disclosure will be described. As described above, AlN also has a stable wurtzite structure as is the case of InN or GaN. Hence, BAlN obtained by mixing B in this AlN layer may also have a wurtzite structure. However, in general, since hexagonal or cubic BN is more stable, a BAlN mixed crystal having a wurtzite structure is difficult to obtain, and it is believed that as a composition ratio of B is increased, the wurtzite structure becomes more difficult to maintain.

For example, in Journal of Crystal Growth 189/190 (1998), pp. 445 to 447 written by M. Shibata, M. Kurimoto, J. Yamamoto, T. Honda, and H. Kawanishi, the formation of a BAlN/GaN quantum well aimed for application to deep ultraviolet emission devices has been reported. This document has reported that the addition of B is limited to at most 13%, and a mixed crystal containing B in an amount more than that is difficult to realize.

In addition, in Physica E 13 (2002), p. 1086 written by L. K. Teles, J. Furthmuller, L. M. R. Scolfaro, A. Tabata, J. R. Leite, F. Bechstedt, T. Frey, D. J. As, and K. Lischka, the results of research on the difficulties of composition control and crystal growth of a BGaN and a BAlN mixed crystal have been reported. In addition, the document described above has also reported the phase separation of zinc blende InGaN, InAlN, BGaN, and BAlN mixed crystals.

As apparent from the documents described above, for example, in an InGaN mixed crystal which is frequently used as an active layer of a semiconductor laser or that of an LED of a nitride semiconductor, in general, an increase in In composition is difficult. In an InGaN mixed crystal, it has been known that when an In composition ratio is increased, the phase separation is liable to occur, and the crystallinity is seriously degraded. The degree of occurrence of this phase separation can be evaluated using the critical temperature in the phase diagram. It is believed that as the critical temperature is decreased, the phase separation is unlikely to occur, and the composition control can be easily performed.

According to the above document written by L. K. Teles et. al., critical temperatures of InGaN and InAlN at each of which, in general, the phase separation is likely to occur are 1,295K and 1,485K, respectively. On the other hand, the critical temperatures of BGaN and BAlN are each approximately 9,000K. For example, since the theoretical calculation is performed on a zinc blende structure (although the BN mixed crystal of the present disclosure has a wurtzite structure), the reliability of calculation should be taken into consideration; however, it is found that the critical temperature of a BN mixed crystal is significantly higher than that of InGaN or the like. That is, it is found that the control of the B composition of each of BGaN and BAlN is seriously difficult, and that a mixed crystal having a high B composition is difficult to realize.

The inventors of the present disclosure has found that in order to obtain a nitride semiconductor layer formed of a BN mixed crystal having a high B content and suppressing the phase separation thereof, when the growth temperature during the crystal growth is decreased, and when the growth conditions are optimized, a BAlN mixed crystal and a BGaN mixed crystal, each having a high B composition ratio of several percent to several tens of percent can be realized. The details will be described with reference to Examples.

Next, the hetero-epitaxial relationship between BAlN having a wurtzite structure and diamond will be described. For example, the case is assumed in which a nitride semiconductor layer formed of BAlN having a wurtzite structure is used as an underlayer, and the (111) plane of diamond is hetero-epitaxially grown on the (0001) plane of this underlayer. In this case, the in-plane epitaxial relationship is expected such that the <1-10> direction of diamond and the <10-10> direction of BAlN are in parallel to each other. The reason for this is based on the hetero-epitaxial relationship between the AlN (0001) plane and the Si (111) plane. (However, it has also been reported that in the hetero-epitaxial growth of diamond and AlN, the <1-10> direction of diamond and the <11-20> direction of AlN are in parallel to each other in the plane.)

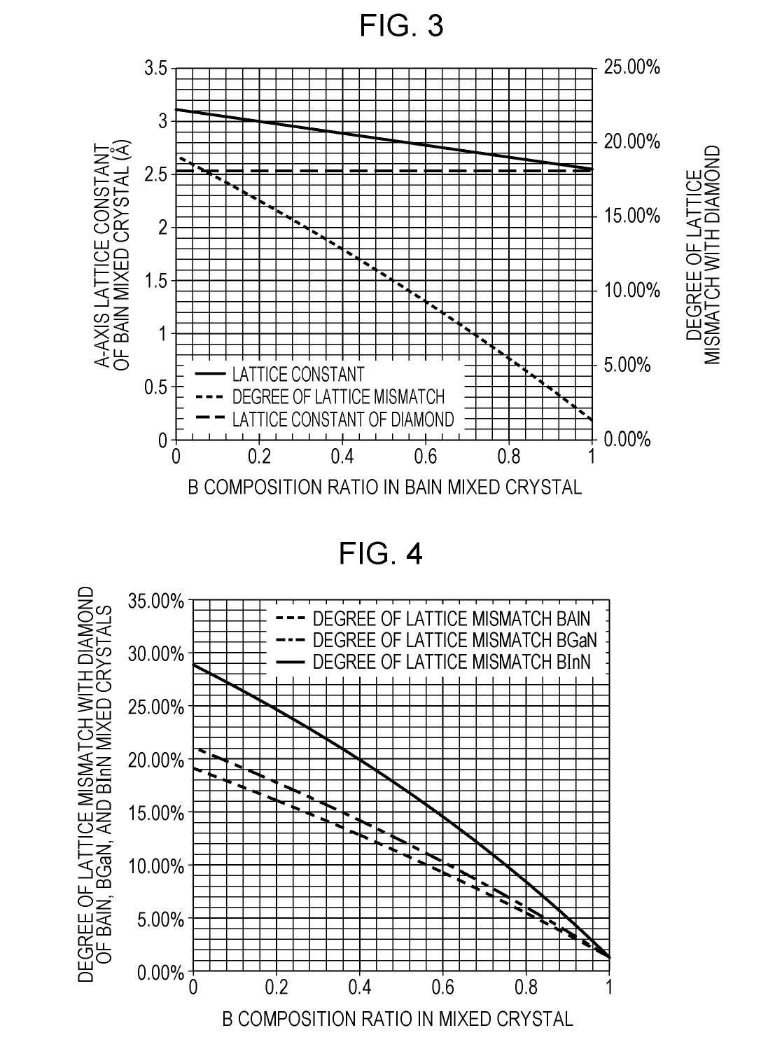

In the case described above, the B composition ratio dependence of the in-plane lattice constant of BAlN and the degree of lattice mismatch with a diamond layer are shown in FIG. 3. It is found that as the B composition ratio in BAlN is increased, the lattice constant is decreased close to the lattice constant (d(−110)=2.52 Å) of diamond shown in the figure. Hence, the degree of lattice mismatch is also decreased as the B composition ratio is increased.

When the B composition ratio is 0, that is, when the underlayer is an AlN layer, the degree of lattice mismatch is approximately 19%. Although this degree of lattice mismatch is remarkably high, it is believed that hetero-epitaxial growth of diamond can be performed. For example, although hetero-epitaxial growth of an AlN layer on the (111) plane of Si causes the degree of lattice mismatch approximately equivalent to that described above, it has been already known that an AlN layer can be epitaxially grown on the (111) plane of Si. That is, it is possible to hetero-epitaxially grow a diamond layer on an AlN layer having a B composition ratio of 0.

However, in order to hetero-epitaxially grow a diamond layer, from a quality point of view, the degree of lattice mismatch between the underlayer and diamond is desirably small. Hence, the B composition ratio is desirably higher.

As a BN mixed crystal on which a diamond layer can be hetero-epitaxially grown, a ternary mixed crystal, such as BGaN or BInN, may also be mentioned by way of example. FIG. 4 shows the degree of lattice mismatch with a diamond layer in the case in which as the underlayer, BAlN, BGaN, and BInN mixed crystals are used. As is the results shown in FIG. 3, as the B composition ratio is increased, the degree of lattice mismatch with a diamond layer is decreased. However, since GaN or InN has a larger lattice constant than that of AlN, the degree of lattice mismatch of BGaN or BInN is higher than that of BAlN.

From those described above, it is found that the diamond multilayer structure of the present disclosure can use a nitride semiconductor having a wurtzite structure and containing B and at least one another group-III element as an underlayer for hetero-epitaxial growth of a diamond layer. In particular, it is believed that a BAlN layer having a wurtzite structure, which can minimize the degree of lattice mismatch, is the most desirable underlayer substrate for diamond hetero-epitaxial growth.

The outlines of a diamond multilayer structure, a substrate for forming diamond semiconductor, a diamond semiconductor device, and a method for manufacturing a diamond multilayer structure of the present disclosure are as described below.

[Item 1] A diamond multilayer structure comprises: a nitride semiconductor layer that have a first main surface and a second main surface and comprises a nitride semiconductor having a wurtzite structure and containing B; and a diamond layer located on the first main surface of the nitride semiconductor layer. According to this structure, since the nitride semiconductor layer having a wurtzite structure is provided, the diamond layer can be epitaxially grown on the nitride semiconductor layer. In addition, since this nitride semiconductor layer can be formed on a substrate, the diameter of which can be easily increased, a larger area diamond multilayer structure can also be manufactured.

[Item 2] The diamond multilayer structure according to the above item 1 further comprises: a substrate that is located at a second main surface side of the nitride semiconductor layer and supports the nitride semiconductor layer, the substrate comprising Si or sapphire. According to this structure, since including a substrate comprising Si or sapphire which is inexpensive, which is easily commercially available, and which can be easily formed to have a larger diameter, a diamond multilayer structure having a large area can also be realized at a low cost.

[Item 3] In the diamond multilayer structure according to the above item 1 or 2, the first main surface of the nitride semiconductor layer is a (0001) plane.

[Item 4] In the diamond multilayer structure according to any one of the above items 1 to 3, the diamond layer is an epitaxial growth layer which is grown depending on the crystallinity of the nitride semiconductor layer.

[Item 5] In the diamond multilayer structure according to the above item 2, the nitride semiconductor layer is an epitaxial growth layer which is grown depending on the crystallinity of the substrate.

[Item 6] In the diamond multilayer structure according to any one of the above items 1 to 5, the nitride semiconductor layer has a composition represented by AlₐB_{b}Ga_{c}In_{d}N (0≦a<1, 0.08≦b≦1, 0≦c<1, 0≦d<1, and a+b+c+d=1).

[Item 7] A substrate for forming diamond semiconductor comprises: a substrate layer; and a nitride semiconductor layer that has a first main surface and a second main surface and is supported by the substrate layer, the nitride semiconductor layer comprising a nitride semiconductor having a wurtzite structure and containing B.

[Item 8] A semiconductor device comprises: the diamond multilayer structure according to any one of the items 1 to 6.

[Item 9] A method for manufacturing a diamond multilayer structure, comprises: (a) preparing a substrate; (b) epitaxially growing a nitride semiconductor layer on the substrate, the nitride semiconductor layer comprising a nitride semiconductor having a wurtzite structure and containing B and having a first and a second main surface; and (c) epitaxially growing a diamond layer on the nitride semiconductor layer.

[Item 10] In the method for manufacturing a diamond multilayer structure according to the above item 9, by alternately supplying a gas containing a group-III element and a gas containing nitrogen into a reaction chamber in the step (b), the nitride semiconductor layer is formed by a metal organic chemical vapor deposition method.

### First Embodiment

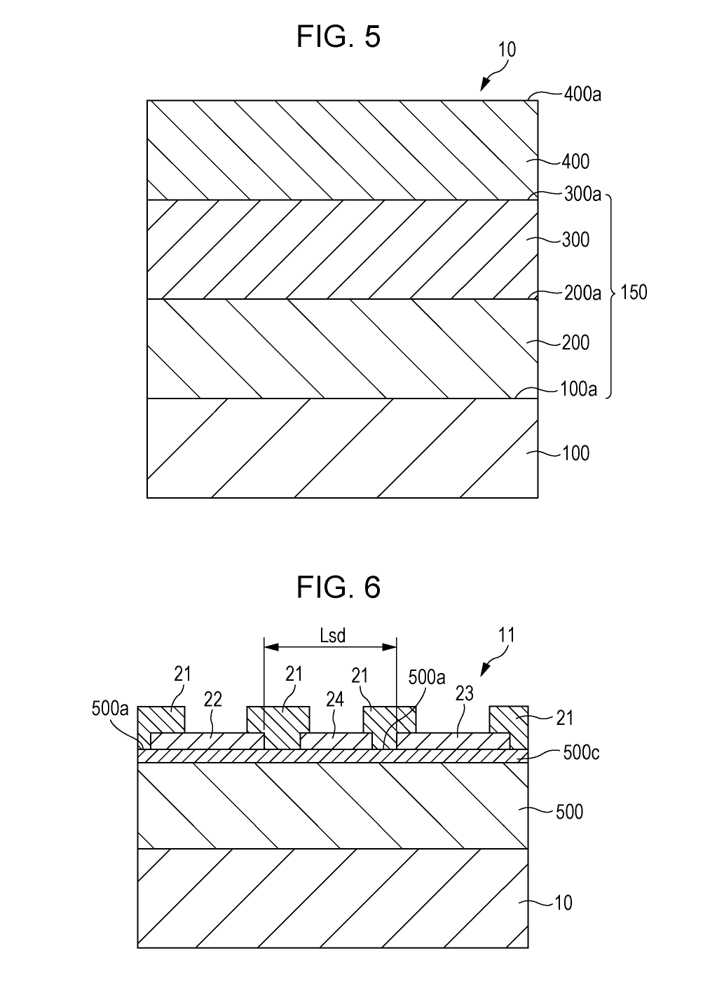

Hereinafter, with reference to the drawings, a substrate for forming diamond semiconductor, a diamond multilayer structure, and a method for manufacturing the same of the present disclosure will be described. FIG. 5 is a cross-sectional view of a diamond multilayer structure of this embodiment.

A diamond multilayer structure 10 of this embodiment comprises a substrate 100, an underlayer 150 supported by the substrate 100, and a diamond layer 400 epitaxially grown on the underlayer 150. In this embodiment, the underlayer 150 includes a buffer layer 200 and a nitride semiconductor layer 300. The underlayer 150 may include at least the nitride semiconductor layer 300 and may include no buffer layer 200. The substrate 100 and the underlayer 150 supported thereby collectively form the substrate for forming diamond semiconductor. Hereinafter, the individual constituent elements will be described in detail.

### 1. Substrate 100

The substrate 100 supports the underlayer 150 and the diamond layer 400. The type of substrate 100 may be appropriately selected so that the nitride semiconductor layer 300 of the underlayer 150 may have a wurtzite structure. In order to control the crystal orientation of the nitride semiconductor layer 300 of the underlayer 150, the substrate 100 desirably has crystallinity and is desirably formed from a single crystal material.

For example, the substrate 100 may be formed of single crystal Si using the (111) plane as a main surface 100a. On the (111) plane of Si, a nitride semiconductor layer having a wurtzite structure can be grown by using the (0001) plane, which is the c plane, as a main surface. In addition, the substrate 100 may be formed of single crystal Si using the (110) plane as the main surface 100a. Even on this crystal plane, a nitride semiconductor layer having a wurtzite structure can also be formed using the (0001) plane as the main surface.

The substrate 100 may be formed of single crystal sapphire using the (0001) plane as the main surface 100a. On this crystal plane, a nitride semiconductor layer having a wurtzite structure can also be formed using the (0001) plane as the main surface.

The substrate 100 may be formed of single crystal sapphire using the m plane as the main surface 100a. The m plane includes the (1-100) plane and the planes equivalent thereto, that is, the (-1010) plane, the (01-10) plane, the (0-110) plane, the (10-10) plane, and (-1100) plane. On a sapphire substrate using this m plane as the main surface 100a, a nitride semiconductor layer having a wurtzite structure can be grown by using the m plane as the main surface.

The substrate 100 may be formed of single crystal sapphire using the r plane as the main surface 100a. The r plane is a plane inclined form the m-axis by 32° to the c-axis direction and is the (10-12) plane. On a sapphire substrate using this r plane as the main surface, a nitride semiconductor layer having a wurtzite structure can be grown by using the a plane as the main surface. The a plane includes the (11-20) plane and the planes equivalent thereto, that is, the (-12-10) plane, the (2-1-10) plane, the (-2110) plane, the (1-210) plane, and the (-1-120) plane.

The substrate 100 may be formed of single crystal sapphire using a plane having the normal inclined from the m-axis to the c-axis direction (that is, a plane inclined from an m plane having no off angle to the c-axis direction) as the main surface 100a. On a sapphire substrate using the plane as described above as the main surface, a nitride semiconductor layer having a wurtzite structure can be grown by using the (11-22) plane, the (11-23) plane, or the (11-24) plane as the main surface.

The substrate 100 may be formed of 4H-SiC or 6H-SiC using the (0001) plane as the main surface. On the crystal plane of this SiC, a nitride semiconductor layer having a wurtzite structure can be grown by using the (0001) plane as the main surface.

The substrate 100 may have the structure in which a (111) plane oriented 3C-SiC layer is formed on a Si substrate using the (111) plane as the main surface. On the structure described above, a nitride semiconductor layer having a wurtzite structure can be grown by using the (0001) plane as the main surface.

2. Buffer Layer 200

The buffer layer 200 is used to form the nitride semiconductor layer 300 having a wurtzite structure. Hence, the buffer layer also desirably has crystallinity and is desirably a single crystal layer. When the nitride semiconductor layer 300 having a wurtzite structure can be directly formed on the substrate 100, the buffer layer 200 may be omitted. In general, in a nitride semiconductor layer 300 having the composition which will be described later, the hexagonal structure and the cubic structure are stable, and the wurtzite structure is metastable. Hence, it may be difficult in some cases to directly form the nitride semiconductor layer 300 having a wurtzite structure on the main surface 100a of a sapphire substrate, a Si substrate, or the like, having a different crystal structure.

The buffer layer 200 may be formed of AlN. When the substrate 100 described above is formed of single crystal Si using the (111) plane as the main surface 100a or single crystal sapphire using the (0001) plane as the main surface 100a, by the use of an AlN layer as the buffer layer 200, the nitride semiconductor layer 300 having a wurtzite structure can be formed. Since AlN has a lattice constant similar to that of diamond and a nitride semiconductor layer 300 having the composition which will be described later as compared to that of GaN or InN, AlN is a desirable material forming the buffer layer 200. In addition, in the case described above, since AlN having a wurtzite structure can be formed on the main surface 100a of the substrate 100, the nitride semiconductor layer 300 having a wurtzite structure is also likely to be formed.

The buffer layer 200 may be formed of GaN. Although the degree of lattice mismatch thereof with the nitride semiconductor layer 300 is increased as compared to that with AlN, an effect similar to that by AlN may also be obtained. In addition, the buffer layer 200 may be a mixed crystal layer of AlN and GaN or may have a multilayer structure in which at least one AlN layer and at least one GaN layer are alternately laminated to each other.

The buffer layer 200 may be formed of cubic 3C-SiC. The 3C-SiC layer can be formed on the substrate 100 of Si using the (111) plane as the main surface 100a, and the (111) plane of the cubic 3C-SiC is oriented.

For example, the buffer layer 200 may have a thickness of 10 to 300 nm. The buffer layer 200 may contain an n-type impurity, such as Si, Ge, or Zn, or may contain a p-type impurity, such as Mg or Be. Accordingly, an n-type or a p-type electrical conductivity can be imparted to the buffer layer 200.

### 3. Nitride Semiconductor Layer 300

The nitride semiconductor layer 300 is in contact with a main surface 200a of the buffer layer 200 located on the substrate 100 and is supported by the substrate 100 with the buffer layer 200 interposed therebetween. When the buffer layer 200 is not provided, the nitride semiconductor layer 300 is in direct contact with the main surface 100a of the substrate 100. The nitride semiconductor layer 300 also desirably has crystallinity and is desirably a single crystal layer. The nitride semiconductor layer 300 is an epitaxial growth layer which is grown depending on the crystallinity of the substrate 100 with the buffer layer 200 interposed therebetween.

The nitride semiconductor layer 300 comprises a nitride semiconductor containing B and has a wurtzite structure. In particular, the nitride semiconductor forming the nitride semiconductor layer 300 has a composition represented by the following formula (1).

AlₐB_{b}Ga_{c}In_{d}N (1)

In the above formula, a, b, c, and d satisfy the following equations.

0≦a<1, 0<b≦1, 0≦c<1, 0≦d<1, and a+b+c+d=1

When b further satisfies the equation of 0.081, the difference in lattice constant between diamond forming the diamond layer 400 and the nitride semiconductor forming the nitride semiconductor layer 300 is decreased, and as a result, a diamond layer 400 having a high crystallinity is likely to be formed.

In addition, when c and d values are small, since the mixed crystal ratio of GaN and InN, each of which has a large lattice constant as compared to that of AlN, is decreased, the lattice constant of the nitride semiconductor layer 300 is decreased, and as a result, the degree of lattice mismatch with diamond is decreased. Hence, for example, c and d may be set to 0. That is, the nitride semiconductor forming the nitride semiconductor layer 300 may have a composition represented by the following formula (2).

AlₐB_{b}N (2)

In this formula, a and b satisfy the following equations.

0≦a<1, 0.08<b≦1, and a+b=1

A main surface (first main surface) 300a of the nitride semiconductor layer 300 is desirably the (0001) plane. When the nitride semiconductor layer 300 is controlled in this plane direction, a diamond layer 400 using the (111) plane as a main surface can be easily formed, and the crystal quality of the diamond layer 400 can be increased. However, the main surface 300a of the nitride semiconductor layer 300 is not required to be the (0001) plane and may be the a plane, the m plane, or a plane which is obtained by inclining the a plane, such as the (11-22) plane, the (11-23) plane, or the (11-24) plane. That is, as long as the nitride semiconductor layer 300 has a wurtzite structure, the plane direction thereof is not limited.

When the nitride semiconductor layer 300 as described above is formed, the hetero-epitaxial growth of the diamond layer 400 can be realized.

For example, the nitride semiconductor layer 300 may have a thickness of 10 to 1,000 nm.

The nitride semiconductor layer 300 may contain an n-type impurity element, such as Si, Ge, or Zn or may contain a p-type impurity element, such as Mg or Be. Accordingly, an n-type or a p-type electrical conductivity can be imparted to the nitride semiconductor layer 300.

4. Diamond Layer 400

The diamond layer 400 is supported by the substrate 100 with the buffer layer 200 and the nitride semiconductor layer 300 which are interposed therebetween and are located on the substrate 100. The diamond layer 400 is in contact with the main surface 300a of the nitride semiconductor layer 300 and is an epitaxial growth layer epitaxially grown depending on the crystallinity of the main surface 300a of the nitride semiconductor layer 300. The diamond layer 400 is a single crystal.

The plane direction of the diamond layer 400 is depend on the nitride semiconductor layer 300 functioning as the underlayer. The most desirable plane direction of a main surface 400a of the diamond layer 400 is the (111) plane. A diamond layer 400 using the (111) plane as the main surface can be easily obtained when the nitride semiconductor layer 300 functioning as the underlayer has a wurtzite structure and uses the (0001) plane as the main surface 300a. However, the plane direction of the main surface 400a of the diamond layer 400 is not limited to the (111) plane, and another plane direction may also be selected. When the plane direction of the nitride semiconductor layer 300 functioning as the underlayer is appropriately selected, the plane direction of the main surface 400a of the diamond layer 400 can be changed.

For example, the diamond layer 400 has a thickness of approximately 10 nm to 10 mm. As the thickness of the diamond layer 400 is increased, the number of defects in the diamond layer 400 is decreased, and the crystallinity thereof is improved.

The diamond layer 400 may has a multilayer structure formed of a plurality of sub-layers having difference electrical conductivities. For example, a plurality of layers, such as a B-doped p-type diamond layer, an un-doped i-type diamond layer, and a P-doped n-type diamond layer, having different doping concentrations, different conduction types, and the like may be included. When the diamond layer 400 has the multilayer structure as described above, the diamond multilayer structure of the present disclosure can be used for an electronic device or a light emission device.

Even when the diamond layer 400 is a single layer, B imparting a p-type conductance or P imparting an n-type conductance may be contained therein.

In addition, after the diamond layer 400 is formed, the substrate 100, the buffer layer 200, and the nitride semiconductor layer 300 may be entirely or partially removed.

According to the diamond multilayer structure of this embodiment, since the nitride semiconductor layer 300 having a wurtzite structure is provided, a diamond layer can be epitaxially grown on the nitride semiconductor layer 300. In addition, since this nitride semiconductor layer 300 can be formed on the substrate 100, the diameter of which can be easily increased, a large area diamond multilayer structure 10 can be manufactured.

### 5. Manufacturing Method

The diamond multilayer structure 10 of this embodiment can be formed by forming the underlayer 150 by a semiconductor epitaxial growth method and by forming the diamond layer 400 by a CVD method or the like. In particular, by a step (1) of preparing the substrate 100, a step (2) of forming the underlayer 150, and a step (3) of forming the diamond layer 400, the diamond multilayer structure 10 can be formed. Hereinafter, the individual steps will be described in detail.

### (1) Step of Preparing Substrate 100

The substrate 100 formed of the above material and having the above plane direction is prepared. When a large diameter substrate 100 formed of Si or sapphire is prepared, a large area diamond multilayer structure 10 can be obtained.

### (2) Step of Forming Underlayer 150

The buffer layer 200 and the nitride semiconductor layer 300 collectively forming the underlayer 150 can be formed on the substrate 100, for example, by a metal organic chemical vapor deposition method (hereinafter referred to as “MOCVD method”), a molecular beam epitaxy (MBE) method, a pulse laser deposition (PLD) method, or an atomic layer deposition (ALD) method. In particular, an MOCVD method is suitable for forming the underlayer 150 on a large diameter substrate 100.

As described above, since the nitride semiconductor layer 300 having a wurtzite structure is metastable, it is not easy to form a high-quality nitride semiconductor layer 300. In the manufacturing method of this embodiment, in order to form a high-quality nitride semiconductor layer 300 containing B, the nitride semiconductor layer 300 is formed at a relatively low temperature. For example, the nitride semiconductor layer 300 is epitaxially grown at a growth temperature of 500° C. to 800° C. Accordingly, the phase separation of at least two group-III nitrides can be suppressed.

In addition, an alternate supply method is used for the growth of the nitride semiconductor layer 300. In particular, a gas containing a group-III element and a gas containing nitrogen, which is a group-V element, are not simultaneously supplied into a growth furnace but are alternately supplied thereinto. As the gas containing a group-III element, for example, an organic metal compound, a hydride, or a chloride, each of which contains Al, Ga, B, In, or the like, is used. In addition, as the gas containing nitrogen, for example, ammonia is used. When the gas containing a group-III element and the gas containing nitrogen are alternately supplied to reduce the physical contact therebetween, the highly reactive gas containing a group-III element and the gas containing nitrogen are suppressed from reacting with each other in a vapor phase, so that serious degradation in crystallinity can be suppressed. In order to more reliably separate the gas containing a group-III element and the gas containing nitrogen in a vapor phase, between a period of supplying the gas containing a group-III element and a period of supplying the gas containing nitrogen, a period of supplying only a carrier gas may be provided. By using an alternate supply method as described above, a nitride semiconductor layer 300 having a high crystal quality can be grown. In addition, since the reaction in a vapor phase is suppressed, migration of a group-III element and nitrogen can be promoted on a crystal growth surface. This phenomenon can compensate for insufficient migration of the raw materials due to low temperature growth of the nitride semiconductor layer 300 and can also contribute to the improvement in crystallinity.

### (3) Step of Forming Diamond Layer 400

The diamond layer 400 can be formed, for example, by a microwave plasma CVD method, a heat filament CVD method, or a direct-current plasma method, each of which has been know as a method for manufacturing a diamond thin film.

When film formation of the diamond layer 400 is started, a negative bias may be applied to the substrate. As a result, a diamond growth nuclei density can be significantly increased.

By the steps described above, the diamond multilayer structure 10 of this embodiment can be manufactured. According to the method of this embodiment, the diamond layer can be epitaxially grown, and the nitride semiconductor layer 300 having a wurtzite structure can be formed to have a high crystal quality. In addition, since this nitride semiconductor layer 300 can be formed on the substrate 100, the diameter of which can be easily increased, a large area diamond multilayer structure 10 can also be manufactured.

### Second Embodiment

An embodiment of a semiconductor device will be described. FIG. 6 is a schematic cross-sectional view showing a semiconductor device 11 of this embodiment. In this embodiment, the semiconductor device 11 is a field effect transistor (FET).

The semiconductor device 11 comprises the diamond multilayer structure 10, a diamond layer 500 located on the first main surface 400a of the diamond layer 400 of the diamond multilayer structure 10, a gate electrode 24, a source electrode 22, and a drain electrode 23, the above three electrodes each being provided on a main surface 500a of the diamond layer 500. The source electrode 22 and the drain electrode 23 are provided with a predetermined gap interposed therebetween, and the gate electrode 24 is disposed between the source electrode 22 and the drain electrode 23.

The diamond layer 500 is formed of un-doped diamond. For example, the diamond layer 500 is formed without adding an impurity used for conduction control. The diamond layer 500 may be doped with B or P to form a channel layer having electrical conductivity.

The main surface 500a of the diamond layer 500 is terminated by hydrogen, a OH group, and/or the like, and hence a surface conductive layer 500c having a sheet carrier concentration of 10¹³ to 10¹⁴ cm⁻² and a mobility of approximately 100 cm²/Vsec is formed in the vicinity of the main surface. After the main surface 500a of the diamond layer 500 is terminated, by adsorption of molecules, such as ozone, NO, and/or NO₂, the sheet carrier concentration may be increased so as to decrease the channel resistance.

The gate electrode 24 provided on the main surface 500a is formed of a material, such as Al, Cu, or Ag, capable of forming a Schottky contact with the surface conductive layer 500c. The source electrode 22 and the drain electrode 23 are formed of a material, such as Au, Ti, or Ni, capable of forming an ohmic contact with the surface conductive layer 500c. A length Lsd between the source electrode 22 and the drain electrode 23 is, for example, 100 nm to 50 μm.

A passivation film 21 suppressing current leakage and the like may be provided on the main surface 500a of the diamond layer 500. As the passivation film, a dielectric film of SiO₂, SiN, ZrO₂, Al₂O₃, HfO₂, or the like may be used.

According to the semiconductor device 11 of this embodiment, a semiconductor device using a diamond semiconductor as the channel can be realized. The semiconductor device 11 can be operated at a high temperature and can also be operated at a high speed with a high withstand voltage. In addition, since the semiconductor device 11 can be formed using a large diameter substrate 100, for example, reduction in manufacturing cost and integration using a plurality of the semiconductor devices 11 can be expected.

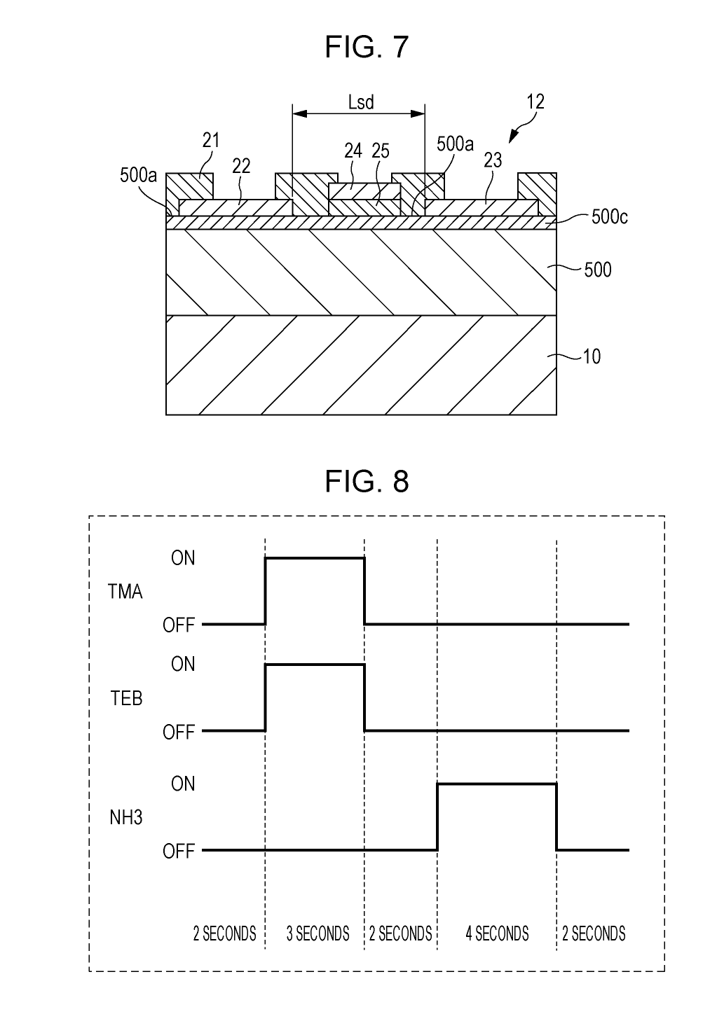

Although the semiconductor device 11 of this embodiment comprises the diamond layer 500, without using the diamond layer 500, the gate electrode 24, the source electrode 22, and the drain electrode 23 may be provided on the main surface 400a of the diamond layer 400 of the diamond multilayer structure 10. In addition, as shown in FIG. 7, an insulating film 25 may be provided under the gate electrode 24 so as to realize a semiconductor device 12 having a MOS structure. In addition, in this embodiment, although the semiconductor device is described with reference to a FET as an example, a device to which the diamond multilayer structure of the first embodiment can be applied is not limited to a FET. For example, when an n-type or a p-type conduction control is performed by using the diamond multilayer structure of the first embodiment, a light emission diode or an electron emission device can also be realized. In addition, by forming a diamond electrode using a p-type conduction control layer, an ozone generation device using an electrochemical reaction can also be realized.

### EXAMPLES

Hereinafter, the formation of the diamond multilayer structure 10 of this embodiment and the measurement results of properties thereof will be described.

### 1. Formation of Diamond Hetero Structure

### Example 1

The diamond multilayer structure 10 shown in FIG. 5 was formed from a substrate, a semiconductor layer, and the like, each of which was formed of the following material and had the following plane direction.

Diamond layer 400;

(0001) plane BAlN layer (thickness: 100 nm) functioning as the nitride semiconductor layer 300;

(0001) plane AlN layer (thickness: 1 μm) functioning as the buffer layer 200; and

(0001) plane sapphire (thickness: 430 μm) functioning as the substrate 100.

The substrate 100 (hereinafter called AlN template) on which the buffer layer 200 was provided was obtained from Dowa Electronics Materials Co., Ltd.

(MOCVD Growth of Nitride Semiconductor Layer 300)

The nitride semiconductor layer 300 was formed on the buffer layer 200 by an MOCVD method. The AlN template was set in an MOCVD apparatus and was then heated while hydrogen and nitrogen were introduced thereinto as a carrier gas. When the temperature of the template reached 600° C., the supply of raw materials was started. That is, the nitride semiconductor layer 300 was grown at a relatively low temperature of 600° C. In the growth of a BAlN layer in which the control of the B composition ratio is expected to be difficult as described in the first embodiment, the above condition is a low temperature growth condition to realize a high B composition ratio.

The main film formation conditions of the nitride semiconductor layer 300 are shown in Table 1. As a supply source of a group-III element, trimethylaluminum (hereinafter called TMA) and triethylboron (TEB) were used, and as a supply source of a group-V element, ammonia (NH₃) was used.

TABLE 1

| Flow rate of TMA | 5.8 | μmol/min |
|---|---|---|
| Flow rate of TEB | 2.7 | μmol/min |
| B composition ratio | 31% | |
| (charge composition ratio) | | |
| Flow rate of ammonia | 0.6 | liter/min |
| Growth pressure | 40 | kPa |

As described in the first embodiment, TMA, TEB, each of which was the supply source of a group-III element, and ammonia were supplied into a growth furnace by an alternate supply method.

FIG. 8 shows a supply timing chart of raw material gases during film formation. Between a supply period (3 seconds) of TMA and TEB and a supply period (4 seconds) of ammonia, a period (2 seconds) of supplying only a carrier gas was provided. In this example, the sequence shown in the figure was regarded as one cycle, and this cycle was repeated 300 times. The thickness of the nitride semiconductor layer 300 thus obtained was approximately 100 nm. The composition of the nitride semiconductor layer 300 can be controlled by primarily adjusting the flow rate ratio between TMA and TEB. The nitride semiconductor layer 300 had a wurtzite structure.

### (Growth of Diamond Layer 400)

Next, the diamond layer 400 was epitaxially grown on the nitride semiconductor layer 300. In this example, the diamond layer 400 was formed by a microwave plasma CVD method.

As raw materials, hydrogen and a methane gas were used. The flow rate of a hydrogen gas and that of a methane gas were set to 300 sccm and 3 sccm, respectively. The growth pressure was set to 6.7 kPa. For the CVD growth of diamond, a method has been proposed in which diamond nuclei were generated by applying a negative voltage bias to the substrate at an initial growth stage. However, in this example, the diamond layer 400 was directly epitaxially grown without using the method described above.

The substrate 100 on which the buffer layer 200 and the nitride semiconductor layer 300 were provided was set in a microwave plasma apparatus, and an electric power of microwave plasma and a growth temperature were set to 1.3 kW and approximately 950° C., respectively. Subsequently, while hydrogen was supplied into the apparatus, the substrate 100 was heated. In addition, the microwave plasma power was also gradually increased to the set value. After the microwave plasma power and the growth temperature reached 1.3 kW and 950° C., respectively, the conditions thus obtained were maintained for 1 minute. Subsequently, a methane gas was supplied, and the growth of the diamond layer 400 was started. The growth time was 3 hours.

### Comparative Example 1

Except that the nitride semiconductor layer 300 was not provided, the diamond layer 400 was formed by exactly the same process as that in Example 1. That is, in FIG. 5, a (0001) plane AlN layer was used as the buffer layer 200, and the diamond layer 400 was directly formed on this buffer layer 200 without using the nitride semiconductor layer 300.

### Example 2

As the substrate 100, a sapphire substrate using the m plane as the main surface was prepared. The substrate 100 had a diameter of approximately 2 inches and a thickness of 0.43 mm.

### (Cleaning of Sapphire Substrate)

The substrate 100 was cleaned by immersion for 10 minutes in a cleaning liquid heated to 100° C. The cleaning liquid was formed of sulfuric acid and phosphoric acid at a volume ratio of 1:1. Subsequently, the substrate 100 was cleaned with water. The cleaning process for this sapphire substrate was not an essential process. It was confirmed that even when this cleaning process was omitted, the buffer layer 200, which was a nitride semiconductor layer, and the nitride semiconductor layer 300 could be formed, and that the properties thereof, such as crystallinity, were not so much changed from those obtained through the cleaning process.

### (Growth of Nitride Semiconductor Layer 300)

In this example, the nitride semiconductor layer 300 was directly formed on the substrate 100 without using the buffer layer 200.

After the substrate 100 was set in an MOCVD apparatus, while hydrogen and nitrogen were allowed to flow therethrough as a carrier gas, a heat treatment was performed at a substrate temperature of 1,000° C. to 1,100° C. for 10 minutes by heating the substrate 100, and the temperature was then decreased. Subsequently, after the substrate temperature reached 550° C., the conditions thus obtained were maintained for 5 minutes, and the supply of raw materials was started. That is, the nitride semiconductor layer 300 was grown at a relatively low temperature of 550° C.

The film formation conditions of the nitride semiconductor layer 300 of this example are shown in Table 2. As a supply source of a group-III element, trimethylaluminum (TMA) and triethylboron (TEB) were used, and as a supply source of a group-V element, ammonia (NH₃) was used.

TABLE 2

| Flow rate of TMA | 5.8 | μmol/min |
|---|---|---|
| Flow rate of TEB | 2.7 | μmol/min |
| B composition ratio | 31% | |
| (charge composition ratio) | | |
| Flow rate of ammonia | 0.3 | liter/min |
| Growth pressure | 40 | kPa |

The growth of the nitride semiconductor layer 300 was performed under the same conditions as those of Example 1 except for the substrate temperature. The thickness of the nitride semiconductor layer 300 thus obtained was approximately 100 nm. In addition, the main surface of the nitride semiconductor layer 300 was the m plane and had a wurtzite structure.

### (Growth of Diamond Layer 400)

Except that the growth time was 2 hours, the diamond layer 400 was grown under the same conditions as those of Example 1.

### Example 3

Except that a nitride semiconductor forming the nitride semiconductor layer 300 had a BGaN composition, a diamond multilayer structure 10 having the same structure as that of Example 2 was formed.

The nitride semiconductor layer 300 was grown as described below. A substrate 100 formed of an m plane sapphire was set in an MOCVD apparatus, and while hydrogen and nitrogen were allowed to flow therethrough as a carrier gas, the substrate 100 was heated. A heat treatment was performed for 10 minutes at a substrate temperature of 1,000° C. to 1,100° C., and the temperature was then decreased. After the substrate temperature reached 550° C., the conditions thus obtained were maintained for 5 minutes, and the supply of raw materials was started. That is, the nitride semiconductor layer 300 was grown at a relatively low temperature of 550° C.

The film formation conditions of the nitride semiconductor layer 300 of this example are shown in Table 3. As a supply source of a group-III element, trimethylaluminum (TMA), triethylboron (TEB), and trimethylgallium (hereinafter called TMG) were used, and as a supply source of a group-V element, ammonia (NH₃) was used.

TABLE 3

| Flow rate of TMA | 16 | μmol/min |
|---|---|---|
| Flow rate of TMG | 34 | μmol/min |
| Flow rate of TEB | 10 | μmol/min |
| B composition ratio | 23% | |
| (charge composition ratio) | | |
| Flow rate of ammonia | 1 | liter/min |
| Growth pressure | 40 | kPa |

In addition, in this example, unlike the case of Example 1 and 2, a group-III gas and a group-V gas were simultaneously supplied to grow the nitride semiconductor layer 300. After TMA was only supplied for 10 minutes before the growth, the nitride semiconductor layer 300 was grown. The growth time was 30 minutes. The nitride semiconductor layer 300 thus obtained had a thickness of approximately 100 nm. In addition, the main surface of the nitride semiconductor layer 300 was the m plane and had a wurtzite structure.

### (Growth of Diamond Layer 400)

Except that the growth time was 2 hours, the diamond layer 400 was grown under the same conditions as those of Example 1.

### Comparative Example 2

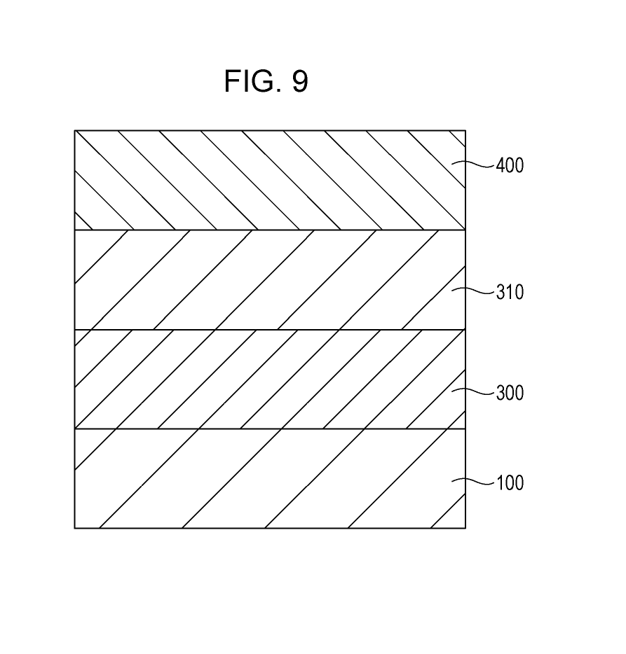

Except that in the diamond multilayer structure of Example 3, a GaN layer 310 was further provided between the nitride semiconductor layer 300 and the diamond layer 400, a diamond multilayer structure was formed by exactly the same process as that of Example 3. The diamond multilayer structure of Comparative Example 2 is shown in FIG. 9.

The GaN layer 310 was grown by an MOCVD method. The substrate 100 on which the nitride semiconductor layer 300 was formed was set in an MOCVD apparatus, and the temperature was increased to 900° C. After the conditions thus obtained were maintained for approximately 1 minute, the growth of the GaN layer 310 was started. In Table 4, the growth conditions are shown.

TABLE 4

| | | |
|---|---|---|
| Flow rate of TMG | 34 | μmol/min |
| Flow rate of ammonia | 4 | liter/min |
| Growth pressure | 40 | kPa |

The growth time was 30 minutes. In addition, the main surface of the GaN layer 310 thus obtained was the m plane and had a wurtzite structure.

In Table 5, the composition and the plane direction of the nitride semiconductor layer functioning as the underlayer for the diamond layer 400 of each of Examples 1 to 3 and Comparative Examples 1 and 2 are collectively shown.

TABLE 5

| | Nitride semiconductor layer 300 | |
|---|---|---|
| Sample | Composition | Plane direction |
| Example 1 | BAIN | (0001) |
| Example 2 | BAIN | m plane |
| Example 3 | BGaN | m plane |
| Comparative Example 1 | AIN (no nitride | (0001) |
| | semiconductor layer) | |
| Comparative Example 2 | GaN | m plane |

### 2. Measurement and Evaluation of Properties

(Measurement Result of x-Ray Diffraction of Nitride Semiconductor Layer 300 of Example 1)

The structure and the composition of the nitride semiconductor of the nitride semiconductor layer 300 of Example 1 were confirmed. Before the diamond layer 400 was formed, the x-ray diffraction (XRD) measurement of the nitride semiconductor layer 300 was performed.

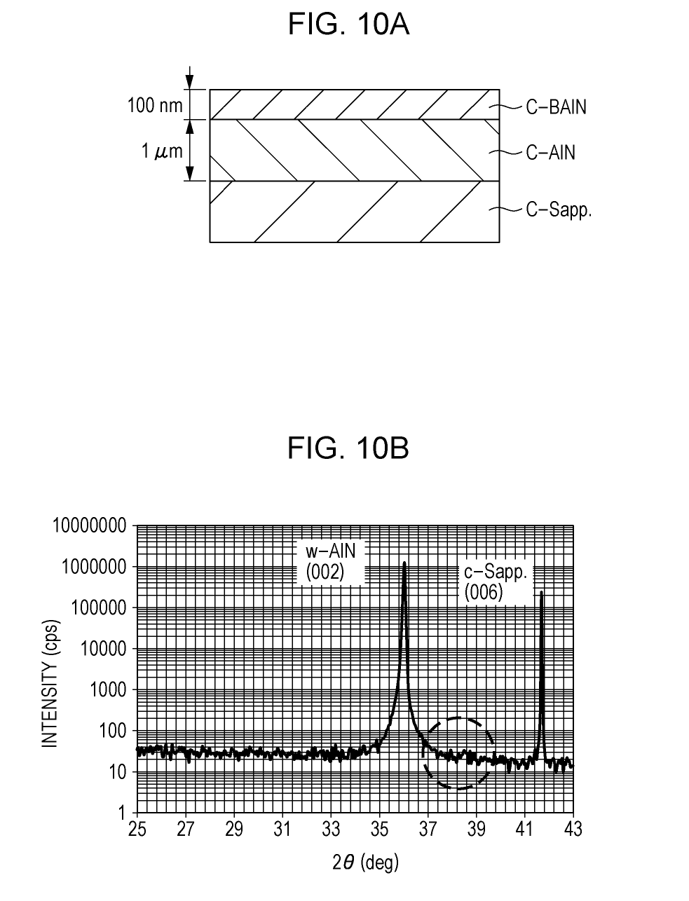

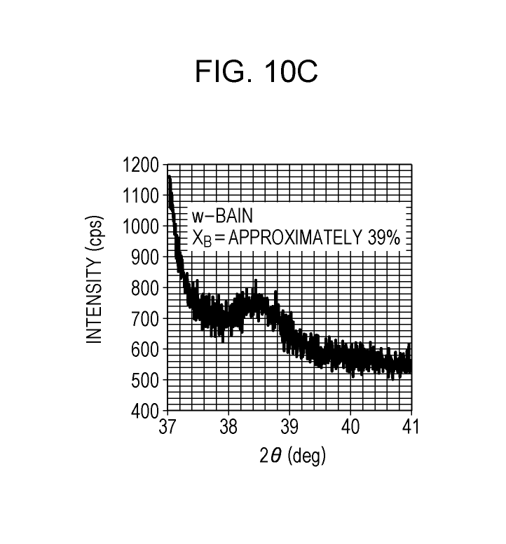

FIG. 10A shows a schematic structure of the diamond multilayer structure of Example 1 before the diamond layer is formed. FIG. 10B sows diffraction peaks in a range of 25° to 43° of 2θ-ω scan, and FIG. 10C shows diffraction peaks in a range of 37° to 41°.

As described above, the stable structure of BN itself is a hexagonal or a cubic crystal. The diffraction peak of hexagonal BN is observed at 2θ=26° to 27°, and the diffraction peak of BN having a wurtzite structure is observed at approximately 2θ=43°.

As shown in FIG. 10B, no diffraction peaks are observed in a range in which the diffraction peak of hexagonal BN is observed, and diffraction peaks are observed between a diffraction angle of the (0002) plane of AlN and that of the (0002) plane of BN having a wurtzite structure.

As shown in FIG. 10C, a diffraction peak (2θ=38.5°) is observed at a higher angle side than AlN. Since observed between AlN and BN having a wurtzite structure, this diffraction peak was regarded as a diffraction peak of a BAlN mixed crystal, and the B composition thereof was estimated approximately 39%.

As described above, one of the reasons a BAlN layer having a wurtzite structure and a high B composition can be formed is believed that the reaction in a vapor phase is sufficiently suppressed by an alternate supply method. As the reasons the diffraction peak of a BAlN mixed crystal is weak, for example, there may be mentioned (1) the film thickness itself is small such as approximately 100 nm, and (2) the conditions of an alternate supply method is not sufficiently optimized. Hence, when the crystallinity of BAlN having a wurtzite structure is improved by optimization of the growth temperature and/or an alternate supply method, it is believed that the crystallinity of a hetero-epitaxially grown diamond film can also be further improved.

### (Measurement Result of X-Ray Diffraction of Nitride Semiconductor Layer 300 of Example 2)

By the procedure similar to that described above, the structure and the composition of the nitride semiconductor of the nitride semiconductor layer 300 of Example 2 were confirmed. Before the diamond layer 400 was formed, the x-ray diffraction (XRD) measurement of the nitride semiconductor layer 300 was performed.

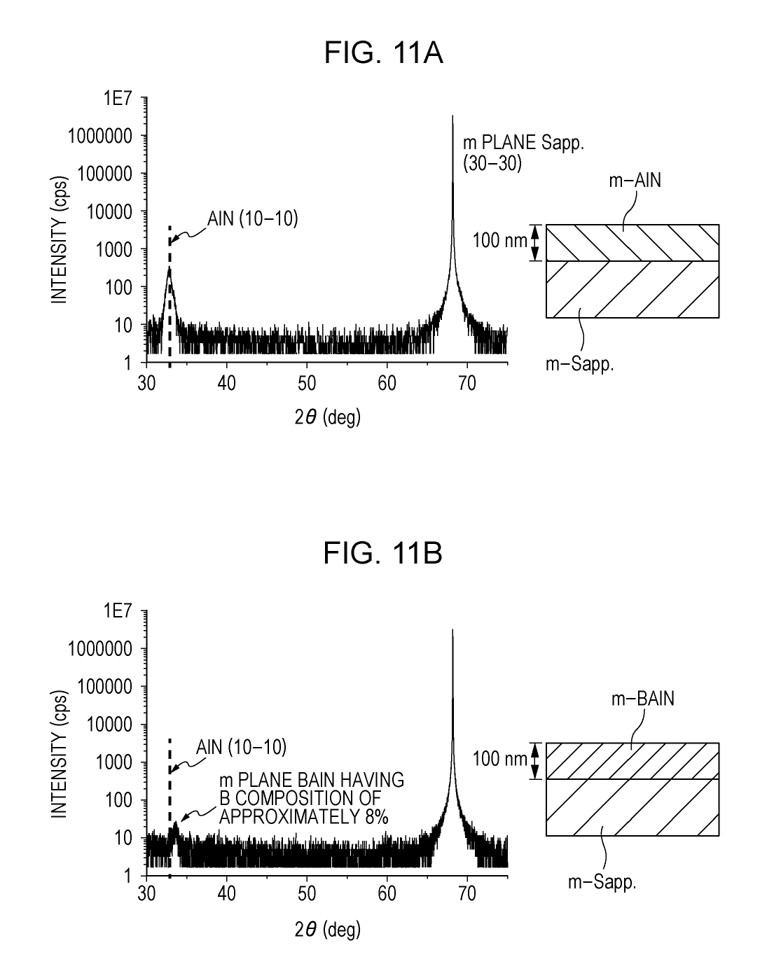

In FIG. 11B, the XRD measurement result of the nitride semiconductor layer 300 of Example 2 is shown. In FIG. 11A, the XRD measurement result of an m plane AlN layer formed on an m plane sapphire substrate is shown. This m plane AlN layer was measured for comparison purpose. As shown in FIG. 11B, a diffraction peak of the (10-10) plane of AlN was observed at approximately 33°. The diffraction peak of Example 2 was observed at a higher angle side than AlN shown in FIG. 11A. The reason for this is believed that the nitride semiconductor forming the nitride semiconductor layer 300 of Example 2 contains B and has a wurtzite structure. The composition of B estimated from the diffraction intensity was approximately 8%. Compared to the nitride semiconductor layer 300 of Example 1, the B composition ratio was remarkably decreased. It is believed that the reason for this is the difference in crystal plane direction and/or the presence or absence of the buffer layer 200. When the crystallinity of the nitride semiconductor layer 300 can be improved by optimization of the conditions of an alternate supply method suitable for the m plane and/or by formation of the buffer layer 200, it is believed that the B composition ratio can be increased.

### (Measurement Result of X-Ray Diffraction of Nitride Semiconductor Layer 300 of Example 3)

By the procedure similar to that described above, the structure and the composition of the nitride semiconductor of the nitride semiconductor layer 300 of Example 3 were confirmed. Before the diamond layer 400 was formed, the x-ray diffraction (XRD) measurement of the nitride semiconductor layer 300 was performed.

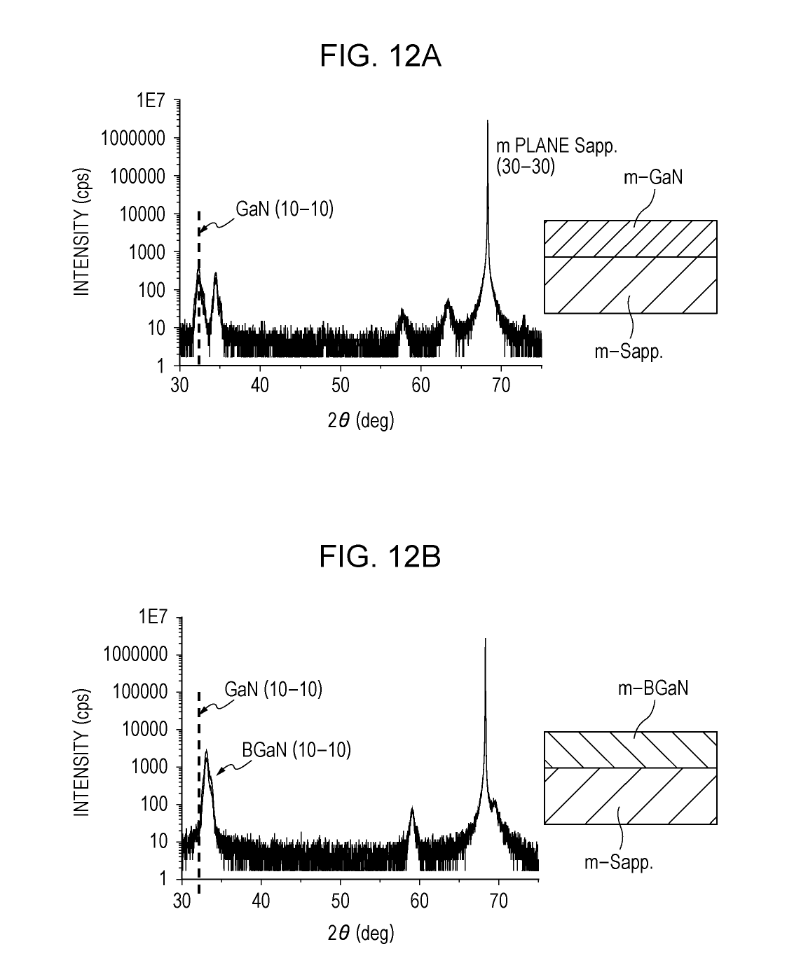

In FIG. 12B, the XRD measurement result of the nitride semiconductor layer 300 of Example 3 is shown. In FIG. 12A, the XRD measurement result of an m plane GaN layer formed on an m plane sapphire substrate is shown. This m plane GaN layer was measured for comparison purpose. As shown in FIG. 12B, a diffraction peak of the (10-10) plane of GaN was observed at approximately 32°. The diffraction peak of Example 3 was observed at a higher angle side than GaN shown in FIG. 12A. The reason for this is believed that the nitride semiconductor forming the nitride semiconductor layer 300 of Example 3 contains B and has a wurtzite structure. The composition of B estimated from the diffraction intensity was approximately 10%.

In both Examples 1 and 2, a diffraction peak from the main surface of the nitride semiconductor mixed crystal (in Example 1, the (002) plane corresponding to the c plane, and in Example 2, the (10-10) plane corresponding to the m plane) was only observed. However, from the nitride semiconductor layer 300 of Example 3, peaks other than those of the m plane GaN having a wurtzite structure and the sapphire functioning as the substrate were also observed, and hence it was estimated that the nitride semiconductor layer 300 was polycrystallized. That is, it was found that the crystallinity of the nitride semiconductor layer 300 of Example 3 was lower than that of each of Examples 1 and 2. However, as apparent from FIG. 12B, among the peaks other than that of the sapphire (substrate), the (10-10) diffraction peak corresponding to the m plane of BGaN was most intensive. Hence, it was found that a BGaN structure having a wurtzite structure was dominant.

### (Diamond Growth Nuclei Density of Diamond Layer of Example 1)

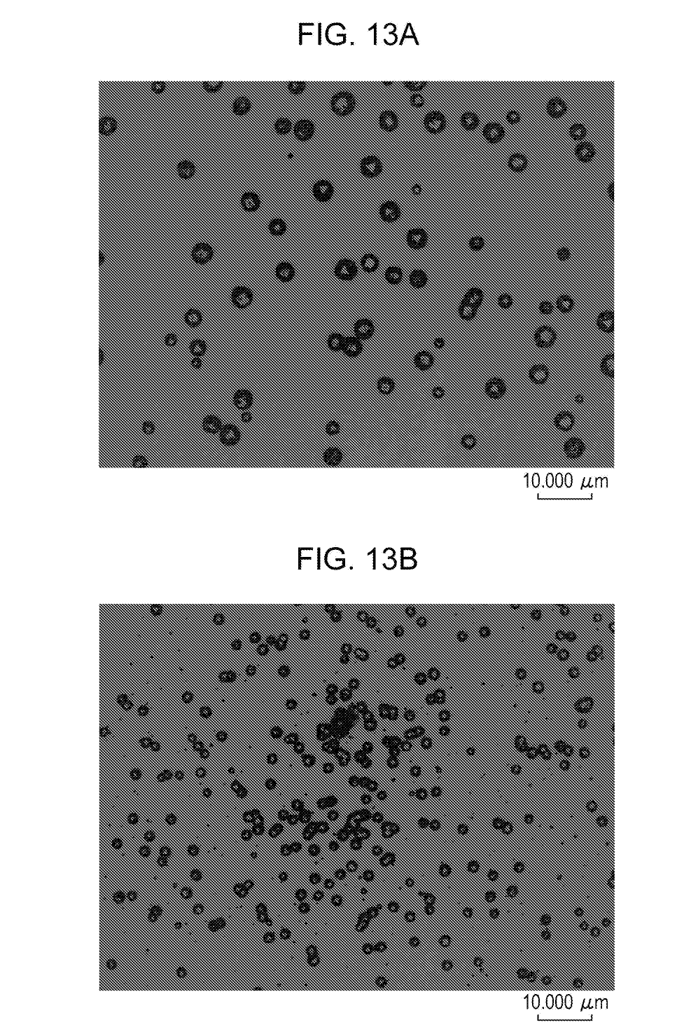

In FIG. 13B, an optical microscope image of the diamond layer 400 of Example 1 is shown. In FIG. 13A, an optical microscope image of the diamond layer 400 of Comparative Example 1 is shown.

In general, it has been known that when a diamond layer is hetero-epitaxially grown, diamond growth nuclei are not likely to be formed on the surface of a hetero substrate. Hence, in general, a method in which hetero-epitaxial growth is performed by applying fine diamond particles on the surface has been proposed. Alternatively, a method in which while a bias is applied to a hetero substrate, growth nuclei are generated by irradiating ions on the surface thereof has also been proposed.

As apparent from FIG. 13A, it was experimentally confirmed that on a c-plane AlN layer having a wurtzite structure, diamond nuclei could be formed at a relatively high density. The reasons for this are believed that even under microwave plasma conditions during diamond layer growth, the AlN layer is stable without receiving thermal damage, and the (0001) plane of the wurtzite structure of AlN has a close epitaxial relationship with the (111) plane of diamond. The diamond growth nuclei density obtained under the conditions of Comparative Example 1 was 1.1×10⁶ cm⁻².

On the other hand, as apparent from FIG. 13B, it is found that under the same conditions as those of Comparative Example 1, a larger number of diamond nuclei are grown on the nitride semiconductor layer 300 of Example 1, and the diamond growth nuclei density is significantly increased. As shown in FIG. 13B, although the distribution of the diamond growth nuclei density is deviated, the density was 7.8×10⁶ cm⁻² as a whole. That is, it was found that although slight deviation was observed in the plane, the diamond growth nuclei density was increased by approximately 3 to 7 times that of Comparative Example 1.

### (Diamond Growth Nuclei Density of Diamond Layer of Example 3)

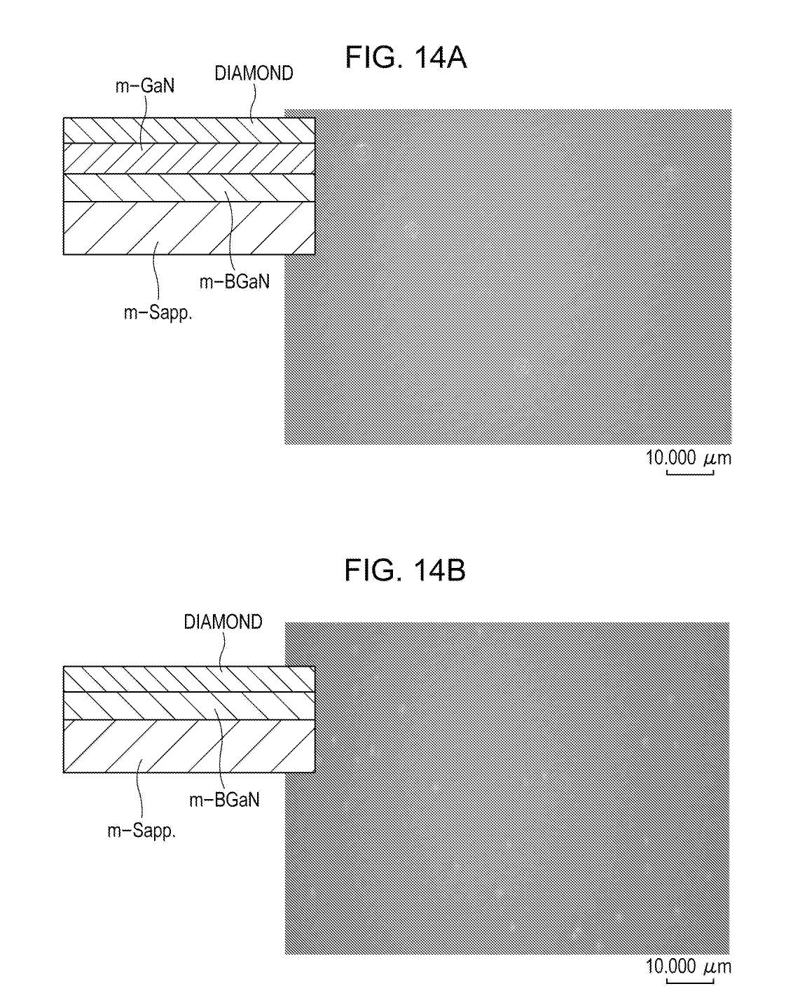

In FIG. 14B, an optical microscope image of the diamond layer 400 of Example 3 is shown. In FIG. 14A, an optical microscope image of the diamond layer 400 of Comparative Example 2.

The diamond growth nuclei densities of Comparative Example 2 and Example 3 were 5.6×10⁴ cm⁻² and 4.5×10⁵ cm⁻², respectively. Although being increased to approximately 10 times that of Comparative Example 2, the diamond growth nuclei density of Example 3 is decreased to less than one tenth of that of Example 1. The results indicate that although a nitride semiconductor having a wurtzite structure is effective as an underlayer of a diamond hetero-epitaxial structure, as compared to GaN and BGaN, AlN and BAlN are more desirable as an under layer for hetero-epitaxial growth of diamond in view of the lattice constant (see FIG. 4) and the thermal stability. In addition, it is believed that since B is contained as a group-III element, the nuclei formation during hetero-epitaxial growth of diamond is promoted.

From the results of Examples 1 and 3 and Comparative Examples 1 and 2 described above, the hetero-epitaxial growth of diamond can be understood as follows.

(1) By the use of a nitride semiconductor having a wurtzite structure as the underlayer, hetero-epitaxial growth of diamond can be performed. As compared to GaN and BGaN, AlN and BAlN, which are stable in microwave plasma and have a lattice constant relatively similar to that of diamond, are more desirably used as the underlayer.
(2) The (0001) plane of a wurtzite structure has a close epitaxial relationship with the (111) plane of diamond. Hence, a high diamond growth nuclei density can be formed as compared to that of another growth plane, such as the m plane. That is, when a nitride semiconductor having a wurtzite structure is used for diamond hetero-epitaxial growth, the (0001) plane is desirably used as the main surface.
(3) In view of the difference in lattice constant, a nitride semiconductor layer using a BAlN mixed crystal is more suitable for the epitaxial growth of diamond than that using AlN, and when a BAlN mixed crystal layer having a wurtzite structure is used as the underlayer, diamond nucleation on the order of approximately 10⁷ cm⁻² can be performed.
(Measurement Results of x-Ray Diffraction of Diamond Layers of Examples 1 and 2)

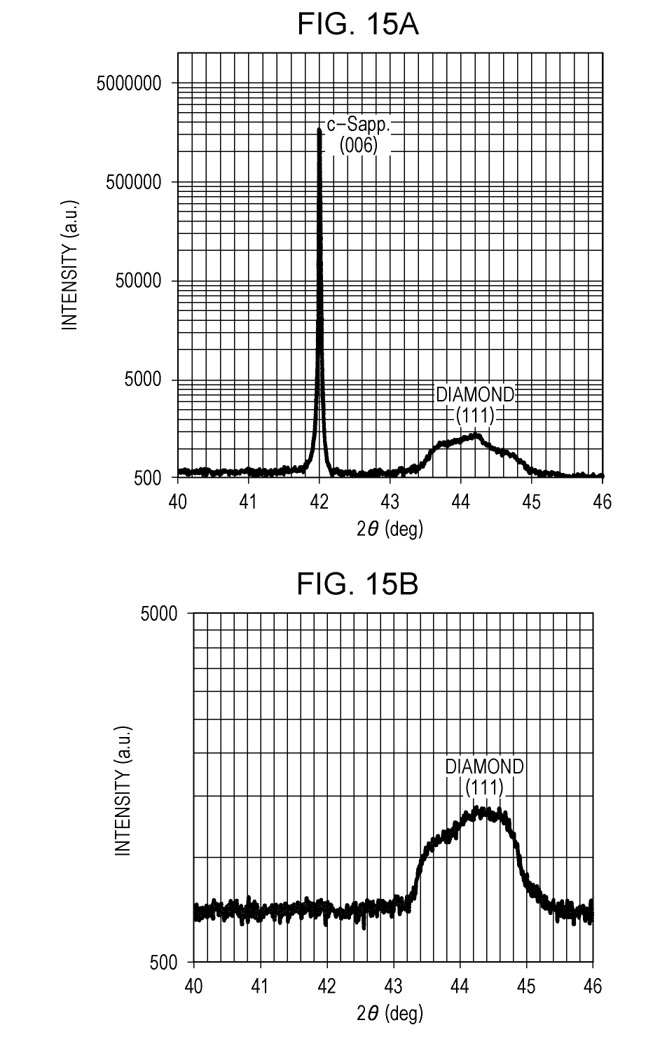

In FIGS. 15A and 15B, the x-ray diffraction measurement results of the diamond layers of Examples 1 and 2 are shown. In the diamond layer of each Example, the x-ray diffraction peak was observed at approximately 44°, which was the diffraction angle of the (111) plane of diamond. From those results, it was found that by the use of a nitride semiconductor having a wurtzite structure, the hetero-epitaxial growth of diamond could be performed, and that the diamond layer thus grown had the (111) plane direction.

As shown in FIG. 15A, according to the result of Example 1, a diffraction peak of the (006) plane of c plane sapphire functioning as the substrate was also simultaneously observed. In Example 1, since the c plane buffer layer 200 was used, a diamond layer using the (111) plane as the main surface was expected to be formed. However, it was found from Example 2 that even when the m plane buffer layer 200 was used in Example 2, that is, even when the buffer layer 200 having a wurtzite structure and a plane direction other than the c plane was used, a diamond layer using the (111) plane as the main surface could also be formed.

### (Evaluation of Diamond Layer of Example 2 by Cross-Sectional Transmission Electron Microscope)

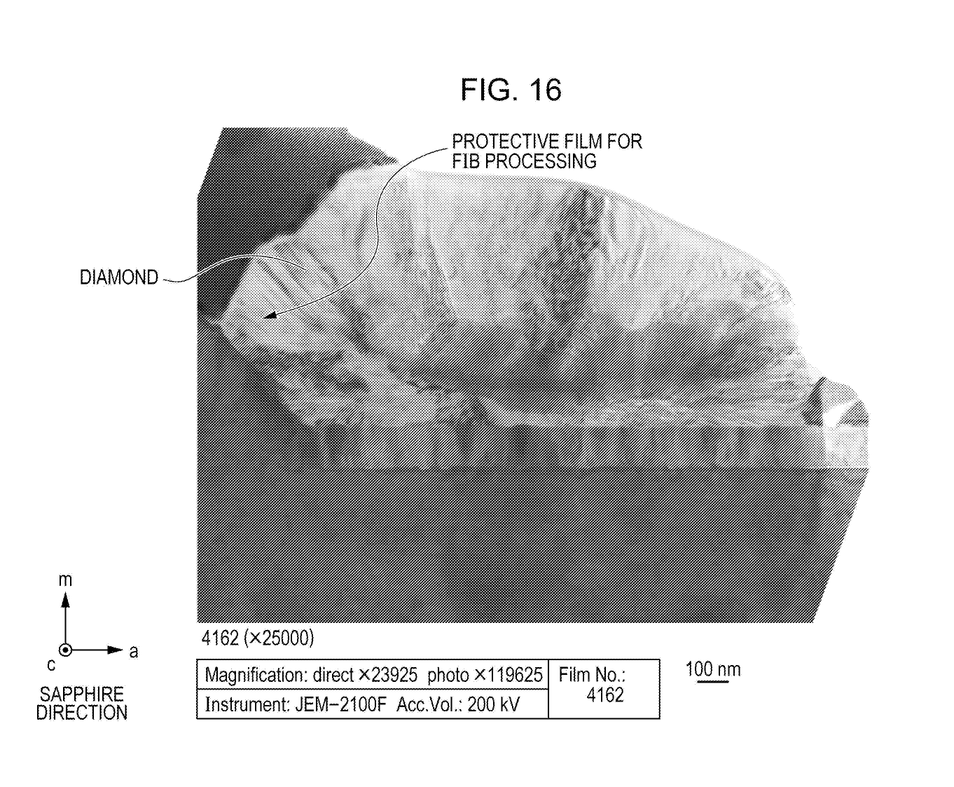

In FIG. 16, a cross-sectional transmission electron microscope image (cross-sectional TEM image) of the diamond layer of Example 2 is shown. The formation of the substrate 100, the nitride semiconductor layer 300, and the diamond layer 400 were confirmed.

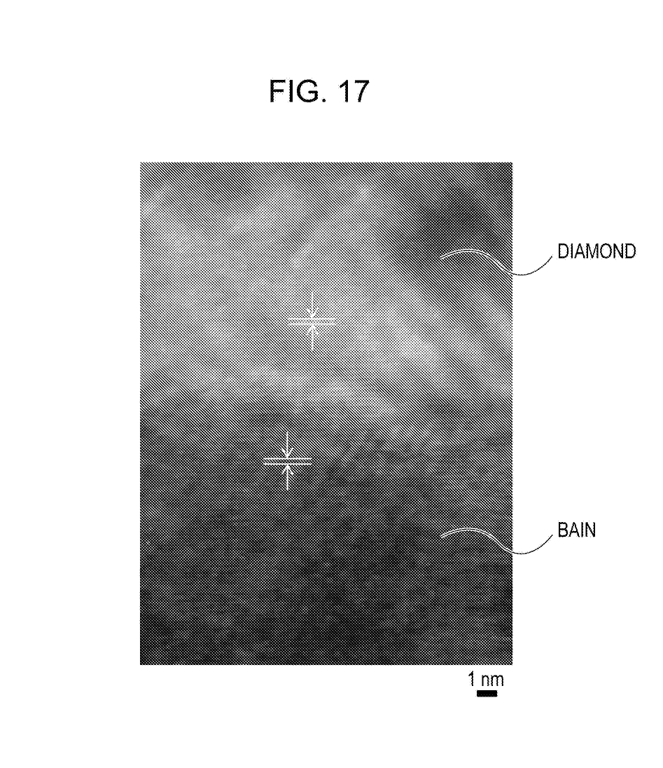

In addition, in FIG. 17, an atomic-level cross-sectional TEM image in the vicinity of the interface between the nitride semiconductor layer 300 and the diamond layer 400 is shown. It was confirmed that a single crystal diamond layer 400 was epitaxially grown on the nitride semiconductor layer 300.

From the results described above, it was confirmed that a single crystal diamond layer or a diamond layer close to a single crystal could be epitaxially grown on a nitride semiconductor layer having a wurtzite structure. In addition, it was also found that as long as a nitride semiconductor layer functioning as the underlayer had a wurtzite structure, the plane direction of the main surface thereof was not limited. That is, it was found that for example, even when the main surface was oriented in the (0001) plane or in the m plane, a diamond layer could be grown.

In addition, the diamond layer of this embodiment is not always required to be a single crystal but may have a polycrystal structure. As is the result of Example 1, when B is added to a wurtzite nitride semiconductor layer functioning as the underlayer, the diamond growth nuclei density is increased. Hence, this embodiment is also effective to form a polycrystal diamond film on a large diameter substrate. The polycrystal diamond film thus formed can be used, for example, as a heat dissipation layer or a heat spreader of a device structure.

The diamond multilayer structure of the present disclosure may be desirably used for various semiconductor devices each using a diamond semiconductor layer.

What is claimed is:

1. A diamond multilayer structure comprising:
a nitride semiconductor layer that have a first main surface and a second main surface and comprises a nitride semiconductor having a wurtzite structure and containing B; and
a diamond layer located on the first main surface of the nitride semiconductor layer.

2. The diamond multilayer structure according to claim 1, further comprising:
a substrate that is located at a second main surface side of the nitride semiconductor layer and supports the nitride semiconductor layer, the substrate comprising Si or sapphire.

3. The diamond multilayer structure according to claim 1, wherein the first main surface of the nitride semiconductor layer is a (0001) plane.

4. The diamond multilayer structure according to claim 1, wherein the diamond layer is an epitaxial growth layer which is grown depending on the crystallinity of the nitride semiconductor layer.

5. The diamond multilayer structure according to claim 2, wherein the nitride semiconductor layer is an epitaxial growth layer which is grown depending on the crystallinity of the substrate.

6. The diamond multilayer structure according to claim 1, wherein the nitride semiconductor layer has a composition represented by AlₐB_{b}Ga_{c}In_{d}N, where 0≦a<1, 0.08≦b<1, 0≦c<1, 0≦d<1, and a+b+c+d=1.

7. A substrate for forming diamond semiconductor, the substrate comprising:
a substrate layer; and
a nitride semiconductor layer that has a first main surface and a second main surface and is supported by the substrate layer, the nitride semiconductor layer comprising a nitride semiconductor having a wurtzite structure and containing B.

8. A semiconductor device comprising a diamond multilayer structure comprising:
a nitride semiconductor layer that have a first main surface and a second main surface and comprises a nitride semiconductor having a wurtzite structure and containing B; and
a diamond layer located on the first main surface of the nitride semiconductor layer.
